(19) United States
(12) Patent Application Publication
(10) Pub. No.: US 2026/0020503 A1
(43) Pub. Date: Jan. 15, 2026

(54) MEMTRANSISTOR DEVICE

(71) Applicant: INDUSTRY-ACADEMIC COOPERATION FOUNDATION, YONSEI UNIVERSITY, Seoul (KR)

(72) Inventors: Woo Young SHIM, Seoul (KR); Ji Hong BAE, Seoul (KR)

(21) Appl. No.: 19/262,788

(22) Filed: Jul. 8, 2025

(30) Foreign Application Priority Data
Jul. 9, 2024 (KR) 10-2024-0090075

(51) Int. Cl. H10N 70/20; H10N 70/00

(52) U.S. Cl. CPC H10N 70/253; H10N 70/245; H10N 70/884

(57) ABSTRACT

An embodiment provides a memtransistor-based electronic device. In particular, according to the embodiment, a synaptic device is provided that may simultaneously utilize ion movement within a van der Waals gap and semiconductor characteristics to control LTP and LTD while simultaneously implementing spike-timing-dependent plasticity (STDP) that is adjustable by a gate voltage. In addition, this conductance control mechanism is applicable to implementing logic operation functions.

### CROSS REFERENCE TO RELATED APPLICATION

The present application claims priority to Korean Patent Application 10-2024-0090075, filed Jul. 9, 2024, the entire contents of which are incorporated here for all purposes by this reference.

### BACKGROUND

The disclosure relates to a memtransistor device.

In computing systems, the von-Neumann CMOS (Complementary Metal-Oxide Semiconductor) integrated circuit system, in which data processing and storage media exist independently, has almost reached its limit in increasing the integration density of devices compared to the system improvement demand that requires continuous improvement in integration density. That is, the integration density of the latest CMOS apparatuses does not follow Moore's law, and its scaling down is also rapidly reaching its physical limit.

In addition, in an environment that requires increasingly complex data processing and high-density data storage, the conventional von Neumann system has limitations in performance improvement due to delays in signal transmission between logic devices and memory devices, and problems with high energy consumption. That is, as the operating frequency and apparatus density increase, power consumption and operating temperature increase, and the time and energy required to transmit data between memory and processor, the performance of the von Neumann system may be seriously degraded.

This phenomenon is particularly prominent in data-centric applications such as real-time image recognition and natural language processing, and in these applications, the von Neumann system cannot surpass the human brain.

Unlike the existing von Neumann system, the human brain has the characteristic of performing computational and memory functions simultaneously through synapses, along with the ability to perform parallel processing using high connectivity. That is, the human brain has about 10¹¹ neurons, which act as low-power computing elements, and between each neuron there are about 10¹⁴ synapses, which act as adaptive memory elements, and through the large-scale parallel structure connected to them, a vast amount of data can be processed in parallel. As a result, the von Neumann system performs better than the human brain in simple calculations, but the human brain performs better in complex environments such as unstructured data classification and pattern recognition.

Therefore, neuromorphic systems composed of neurons and synapse devices are rapidly emerging as future computing technologies that will overcome these limitations, and research is actively being conducted on the development of synapse devices, which are the most core components.

Synapses connect two different neurons whose spike input signals strengthen or weaken the synaptic weight (synaptic plasticity). Data processing and storage can be performed simultaneously by synapse devices. Therefore, the possibility of application to neuromorphic computing systems can be confirmed through the demonstration of artificial synapse devices.

In addition, in-memory computing (IMC) technology, which can perform data storage and computation simultaneously in a single device, is attracting attention as a next-generation computing paradigm. IMC is noteworthy because it can perform computational functions in the memory device itself, enabling logic operations to be implemented without a separate computational circuit. In particular, since a single device can perform memory and logic functions simultaneously, circuit integration can be increased and the structure of the entire system can be simplified, thereby simultaneously securing the advantages of high-speed computation and low-power operation.

Si solid-state synapse devices with conventional silicon-based CMOS structures have been intensively studied in the past as being capable of enabling reliable synaptic plasticity. However, these Si CMOS synapse apparatuses have integration limitations because they require additional materials and device processes, such as the addition of an insulator with ferroelectric properties, to implement synapse devices, and additionally have various problems, such as increased power consumption and device heat generation to drive them.

Memristors are materials whose resistance state changes by the movement of internal ions or vacancies when voltage is applied, and have been extensively studied as nonvolatile memory devices as an alternative to existing silicon-based CMOS structure memories for application to artificial intelligence hardware implementation. However, since only a specific range of resistance state changes are possible for implementing synapse devices, various memory states cannot be stored, and since they have a two-terminal structure, only single synapse characteristics can be implemented, which is a disadvantage.

The recently reported single-layer MoS₂ memtransistor (memristor+transistor) device structure can implement heterosynapse characteristics through dual stimulation of the drain and gate, and can control the resistance state in a wider area than the two-terminal memristor through the gate terminal. Due to these unique characteristics, the memtransistor structure is being actively studied as a synaptic device for implementing next-generation neuromorphic systems.

However, in the case of the current synaptic-mimetic device using van der Waals gap materials, the device-to-device characteristic reproducibility of the switching characteristics is poor because it is dominated by S vacancy defects that occur naturally after the initial synthesis, and it is difficult to finely control the synaptic electrical characteristics, and high power is required because the defects need to move. In addition, since it operates only in a monolayer, it requires a bottom-up synthesis method such as Chemical Vapor Deposition (CVD) synthesis, which is expensive and difficult to synthesize. Due to the above shortcomings, the group of materials that can be operated as a memtransistor is very rare, making it difficult to expand the group of memtransistor materials.

### RELATED ART DOCUMENT

### Patent document

(Patent document 0001) Patent Publication No. 10-2023-0074888

### SUMMARY

The disclosure provides a memtransistor capable of simultaneously utilizing the properties of semiconductor material and ion movement within a van der Waals gap, and a memtransistor synaptic device capable of implementing long-term potentiation (LTP), long-term depression (LTD), and spike-timing dependent plasticity (STDP) through the memtransistor.

The aspect of the disclosure is not limited to that mentioned above, and other aspects not mentioned will be clearly understood by those skilled in the art from the description below.

An embodiment of the disclosure provides a memtransistor device.

A memtransistor device according to an embodiment of the disclosure includes: a substrate; a dielectric layer disposed on the substrate; a group III-V two-dimensional semiconductor layer disposed on the dielectric layer; and source and drain electrodes disposed on the two-dimensional semiconductor layer and spaced apart from each other.

In an embodiment of the disclosure, the group III-V two-dimensional semiconductor layer may be a layered compound represented by chemical formula 1.

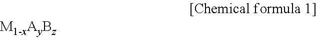

(M is at least one of group 1 and group 2 elements, A is a group III metal element, B is a group V element, and 0<x≤1.0, 0<y≤2.25, 0<z≤2.25)

In an embodiment of the disclosure, the layered compound may further include H and may be represented by chemical formula 2.

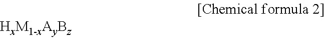

(M is at least one of group 1 and group 2 elements, A is a group III metal element, B is a group V element, and 0<x≤1.0, 0<y≤2.25, 0<z≤2.25)

In an embodiment of the disclosure, the layered compound may include one or more of M₁₋ₓGa_{y}Sb_{z}, M₁₋ₓAl_{y}Sb_{z}, M₁₋ₓGa_{y}N_{z}, M₁₋ₓGa_{y}As_{z}, M₁₋ₓIn_{y}As_{z}, M₁₋ₓIn_{y}P_{z}, M₁₋ₓGa_{y}P_{z} and M_{1- x}In_{y}Sb_{z}.

In an embodiment of the disclosure, the source electrode and drain electrode may form a Schottky junction with the semiconductor layer.

Another embodiment of the disclosure provides a memtransistor synapse device.

A memtransistor synapse device according to an embodiment of the disclosure includes: a substrate; a dielectric layer disposed on the substrate; a group III-V two-dimensional semiconductor layer disposed on the dielectric layer; and source and drain electrodes disposed on the two-dimensional semiconductor layer and spaced apart from each other.

In an embodiment of the disclosure, by applying a first pulse to the drain electrode, the movement of M⁺ ions in the semiconductor layer may be induced to change the electrical conductivity of the semiconductor layer.

In an embodiment of the disclosure, by applying a second pulse to the substrate, the electrical conductivity of the semiconductor layer may be changed.

In an embodiment of the disclosure, the first pulse may be a positive voltage, and by repeatedly applying the first pulse, the electrical conductivity of the semiconductor layer may be increased to implement long-term potentiaton (LTP).

In an embodiment of the disclosure, the first pulse may be a negative voltage, and the first pulse may be repeatedly applied to reduce the electrical conductivity of the semiconductor layer to implement long-term depression (LTD).

In an embodiment of the disclosure, the first pulse may include 1A pulse and 1B pulse applied at intervals, and the second pulse may be applied while the 1B pulse is applied.

Another embodiment of the disclosure provides a memtransistor logic gate device.

A memtransistor logic gate device according to an embodiment of the disclosure includes: a substrate; a dielectric layer disposed on the substrate; a group III-V two-dimensional semiconductor layer disposed on the dielectric layer; and source and drain electrodes disposed on the two-dimensional semiconductor layer and spaced apart from each other.

According to an embodiment of the disclosure, it is possible to provide a memtransistor device capable of simultaneously utilizing ion movement and semiconductor characteristics within a van der Waals gap, and a synapse device and a gate logic device using the same.

The effects of the disclosure are not limited to the effects described above, and should be understood to include all effects that are inferable from the configuration of the disclosure described in the detailed description or claims of the disclosure.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a view showing a memtransistor device according to an embodiment of the disclosure;

FIG. 2 is a view showing an example of implementing a memtransistor synapse device according to an embodiment of the disclosure;

FIG. 3 is a view showing changes in electrical conductivity according to changes in pulse numbers for implementing LTP and LTD of a synapse device according to an embodiment of the disclosure;

FIG. 4 is a view showing changes in synaptic weight according to time for implementing STDP of a synapse device according to an embodiment of the disclosure;

FIG. 5 is a view showing the results of measuring output curves and transfer curves performed to verify semiconductor characteristics of a synapse device according to an embodiment of the disclosure;

FIG. 6 is a view showing changes in electrical characteristics according to ion movement of a synapse device according to an embodiment of the disclosure;

FIG. 7 is a view showing the results of measuring current retention characteristics according to various driving conditions in a time series in a memtransistor device according to the disclosure;

FIG. 8 is a view showing the result of implementing an OR gate using the memtransistor device of the disclosure;

FIG. 9 is a view showing the result of implementing a NOR gate using the memtransistor device of the disclosure;

FIG. 10 is a view showing the change in synaptic weight change according to gate voltage; and

FIG. 11 is a view showing the change in synaptic weight change when gate voltage is applied according to time interval.

### DETAILED DESCRIPTION

Hereinafter, the disclosure will be described with reference to the accompanying drawings. However, the disclosure may be implemented in various different forms and therefore is not limited to the embodiments described herein. In addition, in order to clearly describe the disclosure in the drawings, parts that are not related to the description are omitted, and similar parts are given similar drawing reference numerals throughout the specification.

In the entire specification, when a part is said to be “connected (linked, contacted, coupled)” to another part, this includes not only the case where it is “directly connected” but also the case where it is “indirectly connected” with another member in between. In addition, when a part is said to “include” a component, this does not mean that it excludes other components, unless otherwise specifically stated, but rather that it may include other components.

The terms used in this specification are used only to describe specific embodiments and are not intended to limit the disclosure. The singular expression includes the plural expression unless the context clearly indicates otherwise. In this specification, the terms “include” or “have” are intended to specify the presence of a feature, number, step, operation, component, part, or combination thereof described in the specification, but should be understood as not excluding in advance the possibility of the presence or addition of one or more other features, numbers, steps, operations, components, parts, or combinations thereof.

Hereinafter, embodiments of the disclosure will be described in detail with reference to the accompanying drawings.

### A Memtransistor Device, a Memtransistor Synapse Device, and a Memtransistor Logic Gate Device According to an Embodiment of the Disclosure will be Described

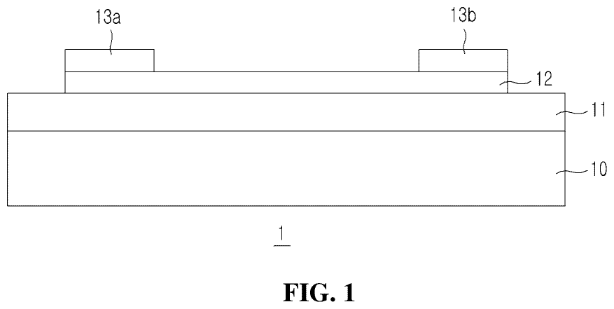

FIG. 1 is a view showing a memtransistor device (1) according to an embodiment of the disclosure.

The memtransistor device (1) of the disclosure corresponds to a three-terminal memtransistor (memtransistor: a compound word of memristor+transistor) device.

Referring to FIG. 1 above, the device (1) according to an embodiment of the disclosure may include a substrate (10), a dielectric layer (11), a two-dimensional semiconductor layer (12), a source electrode (13a), and a drain electrode (13b).

In particular, the memtransistor device (1) of the disclosure can implement not only LTP (Long-term potentiation), LTD (Long-term depression) but also STDP (Spike-timing dependent plasticity) when used as a memtransistor synapse device, and has the characteristic of providing the simplest form of a synapse device that can simulate more complex forms of biological functions through the control of the gate electrode.

Hereinafter, focusing on the memtransistor synapse device according to an embodiment of the disclosure, each component will be specifically described with a focus on the synapse device driving principle.

The memtransistor synapse device of the disclosure has the following two driving principles.
(i) A first driving principle that causes a change in electrical conductivity through ion movement in the van der Waals gap between two-dimensional semiconductor layers (12) caused by applying a pulse to the drain electrode
(ii) A second driving principle that uses the characteristics of semiconductor materials to cause a change in resistance of two-dimensional semiconductor layers (12) by applying a pulse to the gate electrode

If both the first and second driving principles are used, it is possible to simulate a more complex form of biological function as in the implementation example described below.

First, in the device (1) of the disclosure, the substrate (10) may be an heavily doped p⁺ Si substrate or a p⁺⁺ Si substrate. At this time, the substrate serves as a gate electrode in the device. A gate voltage is applied to the substrate (10), and the electric field generated through this can control the current flow between the source electrode (13a) and the drain electrode (13b).

Specifically, when a gate voltage is applied to the substrate (10), a change in the conductivity of the semiconductor layer (12) occurs. For example, in the case where the semiconductor layer (12) is a p-type semiconductor, when a negative gate voltage is applied, the electrical conductivity of the semiconductor layer increases, and when a positive gate voltage is applied, the electrical conductivity decreases.

In the device (1) of the disclosure, the dielectric layer (11) is disposed on the substrate (10) and may include a dielectric material. The dielectric layer (11) may insulate the substrate (10) and the semiconductor layer (12). For example, the dielectric layer (11) may include at least one of silicon oxide (SiO₂), zirconium oxide (ZrO₂), hafnium oxide (HfO₂), boron oxide (B₂O₃), and aluminum oxide (Al₂O₃), and preferably, the dielectric layer (11) may include SiO₂. The dielectric layer (11) may have a thickness of 10 nm to 300 nm.

In the device (1) of the disclosure, the semiconductor layer (12) may be placed on the dielectric layer (11). The semiconductor layer (12) functions as a channel layer and is a layer connecting the source electrode (13a) and the drain electrode (13b), and current may flow between the source electrode (13a) and the drain electrode (13b) through the semiconductor layer (12) via hole transport, depending on the applied voltage.

At this time, in order to implement the two driving principles described above, the semiconductor layer (12) of the disclosure is sufficient if it is composed of a material (driving principle 2) in which ions exist in the van der Waals gap, ion movement is possible (driving principle 1), and semiconductor properties are present. However, in the case of existing van der Waals gap materials (for example, TMDC materials such as MoS₂ or graphene, etc.), if ions are in the van der Waals gap, they change to metallic properties, making it difficult to perform STDP control by applying a pulse to the gate electrode, which is a feature of the disclosure.

Accordingly, the disclosure enables the implementation of the two driving principles described above by having the semiconductor layer (12) in the form of a nanosheet composed of a III-V group two-dimensional semiconductor material, which is a two-dimensional layered material.

Specifically, the III-V group two-dimensional semiconductor material may be represented by chemical formula 1.

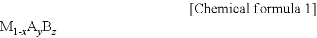

(M is at least one of group 1 and group 2 elements, A is a group III metal element, B is a group V element, and 0<x≤1.0, 0<y≤2.25, 0<z≤2.25)

In addition, the group III-V two-dimensional semiconductor material may further include H and may be represented by chemical formula 2.

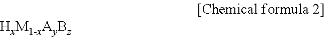

At this time, the A may be a group III metal element, for example, Al, Ga, In,
the B may be a group V element, for example, Sb, N, As, P, and
the M may be at least one of group 1 or group 2 elements, for example, at least one of Na, Li, K, and Ca.

The group III-V two-dimensional semiconductor material may be a layered compound in which the A_{y}B_{z} layers are connected by adding an element M (hereinafter referred to as “added element”) to A_{y}B_{z}, thereby positioning the added element M between the A_{y}B_{z} layers. The added element positioned between the A_{y}B_{z} layers weakly binds the A_{y}B_{z} layers through van der Waals bonds, so that the plane where these added elements are positioned forms a cleavage plane that is easily split along this plane.

The added element M may exist in the M⁺ ion state within the semiconductor layer, and may be mobile within the semiconductor layer.

In addition, the nanosheet forming the semiconductor layer (12) may be formed by overlapping multiple two-dimensional material layers and may have a thickness of several hundred nm. However, it is not limited thereto.

Specifically, the group III-V two-dimensional semiconductor material may be M₁₋ₓGa_{y}Sb_{z}, M₁₋ₓAl_{y}Sb_{z}, M₁₋ₓGa_{y}N_{z}, M₁₋ₓGa_{y}As_{z}, M₁₋ₓIn_{y}As_{z}, M₁₋ₓIn_{y}P_{z}, M₁₋ₓGa_{y}P_{z}, M₁₋ₓIn_{y}Sb_{z}, or, the group III-V two-dimensional semiconductor material may be HₓK₁₋ₓGaSb₂.

In an embodiment, when the group III-V two-dimensional semiconductor material is M₁₋ₓGa_{y}Sb_{z},preferably, M is at least one of group 1 elements, and 0<x≤1.0, 0.75≤y≤1.25, 1.25≤z≤2.25.

In an embodiment, when the group III-V two-dimensional semiconductor material is M₁₋ₓGa_{y}N_{z}, preferably, M is at least one of group 2 elements, and 0<x≤1.0, 0.6≤y≤1.25, 0.75≤z≤1.5.

In an embodiment, when the group III-V two-dimensional semiconductor material is M₁₋ₓGa_{y}P_{z}, preferably, M is at least one of the group II elements, and 0.3≤x≤0.9, 0.6≤y≤2.25, 1.2≤z≤2.25 may be satisfied.

In the device (1) of the disclosure, the source electrode (13a) and the drain electrode (13b) may be disposed on the semiconductor layer (12) and may be disposed spaced apart from each other.

The source electrode (13a) and the drain electrode (13b) may include at least one metal material selected from the group consisting of aluminum, copper, nickel, iron, chromium, titanium, zinc, lead, gold, platinum, palladium, molybdenum, and silver so as to form a Schottky junction (Schottky contact) through bonding with the two-dimensional semiconductor material constituting the semiconductor layer (12).

The source electrode (13a) and the drain electrode (13b) may be formed of at least two layers including the above-described metal. For example, the source electrode (13a) and the drain electrode (13b) may include a first layer and a second layer. At this time, the first layer may be disposed between the semiconductor layer (12) and the second layer to enhance adhesion. For example, the source electrode (13a) and the drain electrode (13b) may be formed of two layers including a Cr layer and an Au layer.

In an embodiment, a first pulse may be applied to the drain electrode (13b) of the device (1) according to an embodiment of the disclosure to induce movement of M⁺ ions in the semiconductor layer, thereby changing the electrical conductivity of the semiconductor layer.

For example, a first pulse, which is a negative voltage, may be repeatedly applied to the device of the disclosure to decrease the electrical conductivity of the semiconductor layer, thereby implementing an LTD state. Conversely, a first pulse, which is a positive voltage, may be repeatedly applied to increase the electrical conductivity of the semiconductor layer, thereby implementing an LTP state.

In addition, a second pulse may be applied to the substrate (10). Through this, the electrical conductivity of the semiconductor layer may be changed.

At this time, the second pulse may be applied only during a portion of the period during which the first pulse is applied. For example, if the first pulse includes 1A pulse and 1B pulse that are applied at intervals, the second pulse may be applied while the first pulse is applied.

In addition, the specific LTP, LTD, and STDP implementation methods of the device will be described in the experimental example section to be described later.

As described above, the memtransistor device of the disclosure may provide a device having a three-terminal structure that can simultaneously implement memristive ion movement characteristics and gate control characteristics of a field-effect transistor by including a two-dimensional semiconductor material of the group III-V series that can maintain stable semiconductor characteristics while including ions that can move within the van der Waals gap as a channel layer.

Accordingly, the memtransistor synaptic device of the disclosure can implement long-term potentiation (LTP), long-term depression (LTD), and even spike-timing-dependent plasticity (STDP) within a single device, and in particular, provides a gate-tunable STDP characteristic that can precisely control the directionality and strength of STDP using the gate voltage. These structural and functional features enable the complex learning mechanisms of biological neural networks to be simulated at the electronic device level, which greatly increases their potential for use as ultra-small, highly integrated synaptic devices for implementing neuromorphic computing systems.

### <Production Example/Experimental Example>

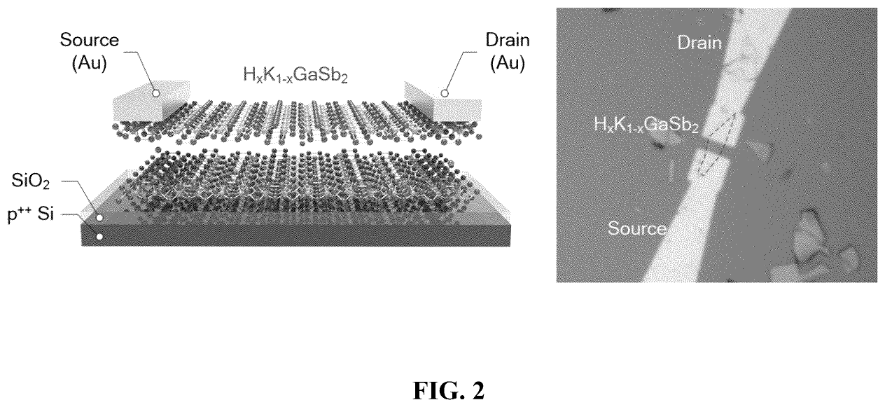

FIG. 2 is a view showing an implementation example of a memtransistor synapse device according to an embodiment of the disclosure.

Hereinafter, a memtransistor synapse device according to an embodiment of the disclosure and a synapse device operating principle will be described together with reference to FIGS. 2 to 6.

A memtransistor synapse device according to an embodiment of the disclosure was manufactured through the following process.

First, a nanosheet peeled from a bulk crystal having a composition of HₓK₁₋ₓGaSb₂ was prepared. The peeling was performed mechanically using scotch tape in a glove box under an argon atmosphere, and the peeled nanosheet was transferred onto a p-type doped Si substrate on which an insulating SiO₂ layer having a thickness of about 300 nm was formed.

The transferred substrate was immersed in acetone for about 30 minutes to remove residual contaminants, and then a photosensitive agent, polymethyl methacrylate (PMMA), was spin-coated on the sample surface. Thereafter, source and drain electrode patterns are formed through e-beam lithography.

The electrodes are formed by depositing gold (Au), and the deposition is performed through thermal evaporation or sputtering. Gold was selected because it has a lower work function than that of HₓK₁₋ₓGaSb_{z}, and can form a Schottky junction (Schottky barrier) at the metal-semiconductor interface when used as a source/drain electrode.

Thereafter, the device patterning process is completed by a lift-off method by immersing in warm acetone. A p-type doped Si substrate was used as the lower gate electrode.

The electrical characteristics of the manufactured device were evaluated under room temperature and atmospheric conditions using a Keithley 4200A semiconductor analyzer.

As illustrated in FIG. 2, a memtransistor synapse device according to an embodiment of the disclosure is characterized by including a dielectric layer composed of SiO₂ on a p⁺⁺ doped Si substrate, a semiconductor layer having a chemical formula represented by HₓK₁₋ₓGaSb₂, and a source electrode/drain electrode.

Among these, the drain electrode enables the driving principle 1. That is, the resistance state of the HₓK₁₋ₓGaSb₂ semiconductor layer is changed through the movement of K⁺ ions in the semiconductor layer. When the K⁺ ions are concentrated toward the drain electrode, it corresponds to a high resistance state (HRS), and when they are concentrated toward the source electrode, it corresponds to a low resistance state (LRS).

Meanwhile, the p⁺⁺ Si substrate acts as a gate electrode and enables the driving principle 2. Due to the characteristics of the semiconductor, the electrical conductivity in the semiconductor layer channel is controlled according to the voltage applied to the gate electrode. Since the HₓK₁₋ₓGaSb₂ of the disclosure is a p-type semiconductor, the electrical conductivity increases when a negative gate voltage is applied, and decreases when a positive gate voltage is applied.

First, a synaptic device according to an embodiment of the disclosure was implemented with long-term potentiation (LTP)/long-term depression (LTD) using only the first driving principle among the driving principles described above.

### <LTP Implementation>

After applying a pulse of 3 V (pulse width: 10 ms) to the drain electrode, the conductance with a read pulse of 1 V (pulse width: 10 ms) is observed. The above process is repeated 20 times to check whether the conductance continues to increase after a series of pulses. When a voltage of 3 V is applied, the K⁺ ions inside the material move toward the source electrode, causing the material's resistance state to reach LRS, thus increasing the conductance.

### <LTD Implementation>

After applying a pulse of −3 V (pulse width: 10 ms) to the drain electrode, the conductance with a read pulse of 1 V (pulse width: 10 ms) is observed. The above process is repeated 20 times to check whether the conductance continues to decrease after a series of pulses. When a voltage of −3 V is applied, the K⁺ ions inside the material move toward the drain, causing the material's resistance state to reach HRS, thus decreasing the conductance.

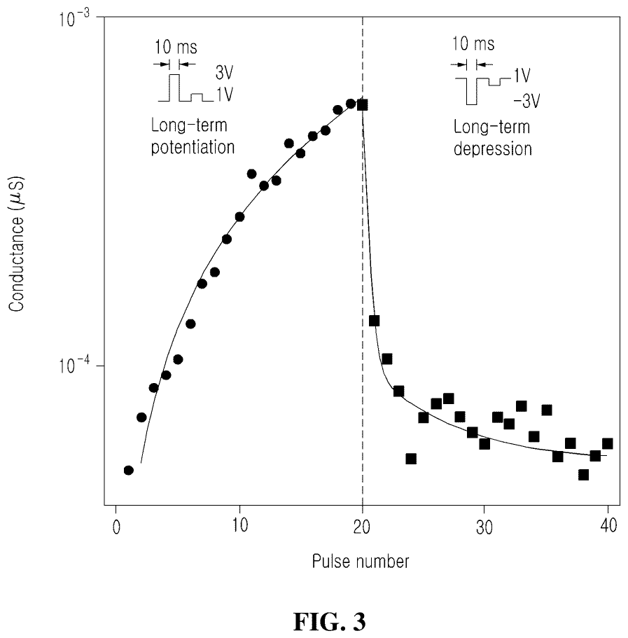

FIG. 3 is a view illustrating the change in electrical conductivity according to the change in the Pulse number for implementing LTP and LTD of a synapse device according to an embodiment of the disclosure.

Since LTP and LTD in actual biology have a biexponential function, it can be confirmed through the fitting curve of FIG. 3 that the synapse device of the disclosure implements LTP and LTD well.

### <STDP Implementation>

Next, spike-timing dependent plasticity (STDP) was implemented using the synapse device according to an embodiment of the disclosure.

Spike-timing dependent plasticity is a mechanism that occurs in a neural network, where a presynaptic neuron transmits an electrical signal called a spike when stimulated, and a neurotransmitter is secreted when the spike reaches the synapse. In this case, the receptor of the postsynaptic neuron recognizes the neurotransmitter and a spike is generated, allowing the signal to be transmitted from the presynaptic neuron to the postsynaptic neuron. At this time, the STDP is a mechanism that controls the strength of the connection between neurons in this process, and can strengthen or weaken the connection between neurons to convert information into long-term memory or to quickly forget it. That is, within the STDP process, the connection between neurons is strengthened and suppressed at the relative interval at which spikes occur in the neurons.

Specifically, if the presynaptic spike occurs before the postsynaptic spike, the presynaptic neuron signal is recognized as having influenced the postsynaptic neuron signal, and the connection between synapses is strengthened.

Conversely, if the presynaptic spike occurs after the postsynaptic spike, the connection between neurons is recognized as being weak, and the connection of the synapse is suppressed.

In the above-described principle, the narrower the interval between spikes, the greater the connection between neurons is recognized, and the greater the change in connection occurs.

Quadrant 1: Positive pulse (3 V, 10 ms) and Read voltage (1 V, 10 ms) were applied twice consecutively, and the change in Conductance (G) measured at the Read voltage was observed. The time interval between the two consecutive pulses was 10 to 90 ms, and since it is the LTP region, it was expressed as Δt>0.

Quadrant 3: Negative pulse (−3 V, 10 ms) and Read voltage (1 V, 10 ms) were applied twice consecutively, and the change in Conductance measured at the Read voltage was observed. The time interval between the two consecutive pulses was 10 to 90 ms, and since it is the LTD region, it was expressed as Δt<0.

Here, the change in Conductance was expressed as Synaptic weight change, and calculated as (G_{After}−G_{Before})/G_{Before}.

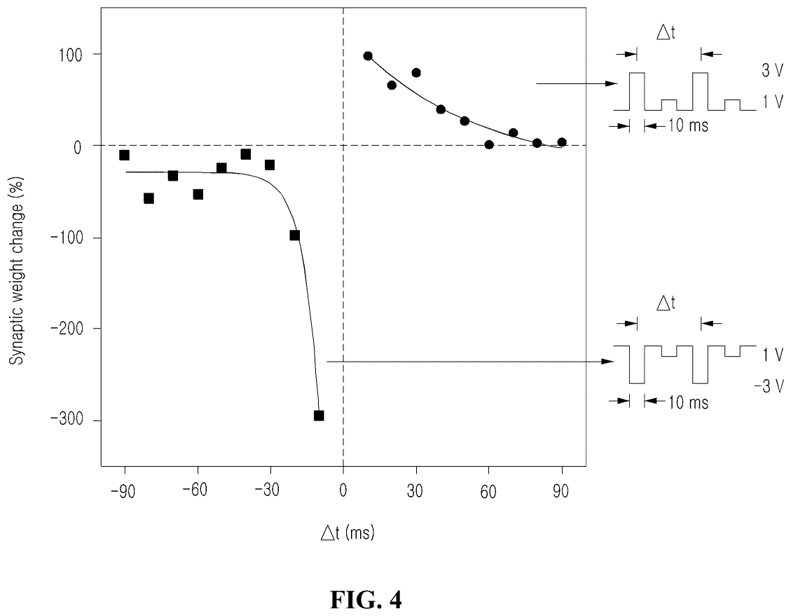

FIG. 4 is a view showing changes in synaptic weight according to time for implementing STDP of a synapse device according to an embodiment of the disclosure.

Since the actual STDP is a biologically exponential function, it can be confirmed through the fitting curve of FIG. 4 that the synaptic device of the disclosure implements STDP well.

### <STDP/LTP/LTD (Gate-Tunable STDP) Implementation>

Next, in order to simulate more biologically complex functions, STDP/LTP/LTD was implemented by simultaneously utilizing the first and second driving principles (Gate-tunable STDP).
(1) It was performed only in the first quadrant method of STDP.
(2) That is, a positive pulse (3 V, 10 ms) and a read voltage (1 V, 10 ms) were applied twice consecutively, and the change in conductance measured at the read voltage was observed. The time interval between the two consecutive pulses was 10 to 90 ms, and since it is the LTP region, it was expressed as Δt>0.
(3) Among the two consecutive pulses, the gate voltage was applied only to the latter pulse. The gate voltage was increased from −80 to 80 V at 10 V intervals.

Biologically, the first quadrant of STDP corresponds to the region of LTP (G_{After}>G_{Before}) because only positive pulses are applied twice consecutively. At this time, the change in conductance, i.e., the synaptic weight change ((G_{After}−G_{Before})/G_{Before}) must be greater than 0.

However, since the gate voltage was applied only to the rear pulse, the value of G_{After} in the synaptic weight change increases or decreases depending on the gate voltage. This becomes G_{After}−G_{Before}>>0 or G_{After}−G_{Before}<0 depending on the gate voltage.

That is, it was confirmed that even in the region of the first quadrant where only positive pulses are applied twice, LTP can be strengthened or LTD can be achieved by applying the gate voltage.

In conclusion, it was shown that the amount of increase or decrease in conductance varies depending on the size of the gate voltage even when the same amount of voltage pulses are applied continuously, and it was confirmed that even under the original LTP condition, LTP can be strengthened or reversed to LTD depending on the gate voltage.

### <Confirmation of the Semiconductor Characteristics of the Device>

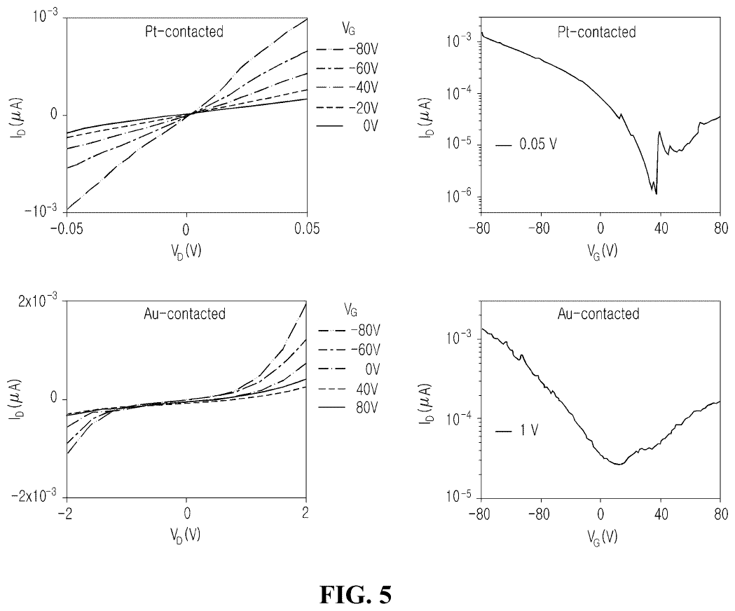

FIG. 5 is a view showing the results of measuring output curves and transfer curves performed to verify semiconductor characteristics of a synapse device according to an embodiment of the disclosure.

In the disclosure, a device using a Pt-contact to form an Ohmic contact, which is generally used for evaluating transistor characteristics, and a device using an Au-contact to form a Schottky contact to evaluate memristor characteristics were fabricated, respectively. The two devices have the same structure as FIG. 1.

The output curve of the Pt-contact device was measured by applying a gate voltage from −80 V to 0 V at 20 V intervals and measuring the drain current, and the transfer curve was measured by changing the gate voltage from −80 V to 80 V at 1 V intervals. Specifically, the maximum current value was obtained in the negative gate voltage region (near −80 V), and the current decreased as it went into the positive gate voltage region. These results clearly prove that this device exhibits p-type semiconductor characteristics.

Meanwhile, the output curve and transfer curve were measured in the same manner using an Au-contact device to confirm the memristor characteristics. For the output curve, the gate voltage was measured at 40 V intervals from −80 V to 80 V, and for the transfer curve, it was measured at 1 V intervals from −80 V to 80 V. Similar to the Pt-contact device, a relatively high current was measured in the negative gate voltage region, and a low current was measured in the positive gate voltage region.

These results demonstrate that the p-type semiconductor characteristics are maintained in the Au-contact device, and in particular, this is the first case in which clear semiconductor characteristics are expressed under the condition that ions exist inside the van der Waals gap.

### <Analysis of Transmission Characteristics and Threshold Voltage Changes of Synaptic Devices>

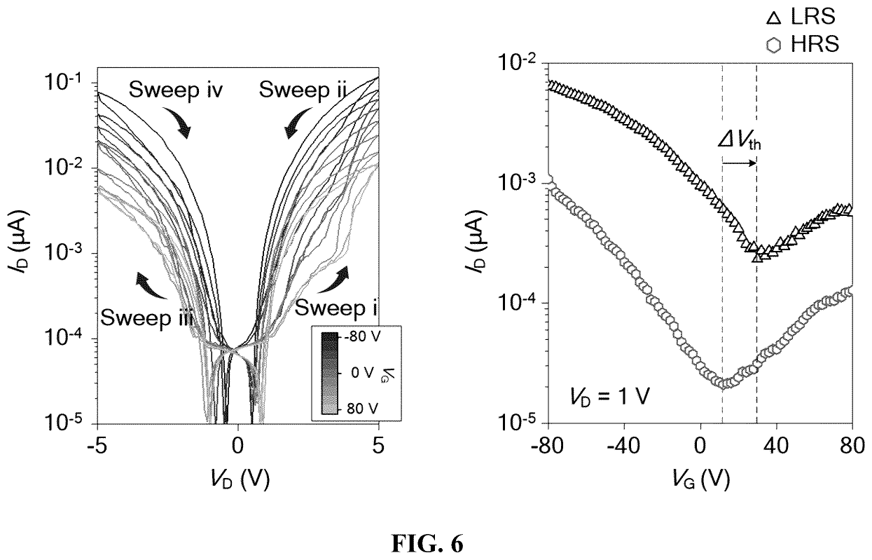

FIG. 6 is a view showing changes in electrical characteristics according to ion movement of a synapse device according to an embodiment of the disclosure.

In an embodiment of the disclosure, the high resistance state (HRS) and low resistance state (LRS) formed by ion movement within the semiconductor layer directly affect the semiconductor characteristics. Specifically, as the resistance state of the semiconductor layer changes depending on the location of the ions, not only the size of the device current but also the threshold voltage is observed to change. This change in the resistance state due to ion movement clearly affects the transfer curve of the transistor according to the gate voltage.

It was confirmed in FIG. 6 that the movement of ions within the van der Waals gap (memristor characteristics) and the semiconductor characteristics are simultaneously expressed. As a result of analyzing the current characteristics according to the gate voltage through the Output curve, in which the conductivity of the semiconductor layer changes depending on the ion movement, it was verified that this device exhibits p-type semiconductor characteristics.

Specifically, the drain voltage was increased from 0 V to 5 V (sweep i), decreased to 0 V again (sweep ii), decreased from 0 V to −5 V (sweep iii), and increased to 0 V again (sweep iv). During this sweep process, the change in conductivity due to the movement of ions was clearly observed, confirming that memristor characteristics were expressed. In addition, as a result of performing the sweep while changing the gate voltage from −80 V to 80 V in 20 V intervals, the conductivity tended to decrease as it went in the positive gate voltage direction, proving that the device of the disclosure is a memtransistor that has both memristor and p-type semiconductor characteristics.

The ion movement of the memtransistor and its influence on the semiconductor characteristics were confirmed in FIG. 6. The transfer curve in the HRS state and the transfer curve in the LRS state were measured, and the transfer curve in the LRS state showed a higher current value than the HRS state at the same read voltage. In addition, specifically, it was confirmed that when ions move toward the source electrode to form an LRS, the threshold voltage required to switch it to the off state tends to shift toward more positive gate voltage.

### <Analysis of Logic Operations Through Electrical Conductivity Change (Ion Movement) and Gate Voltage Control>

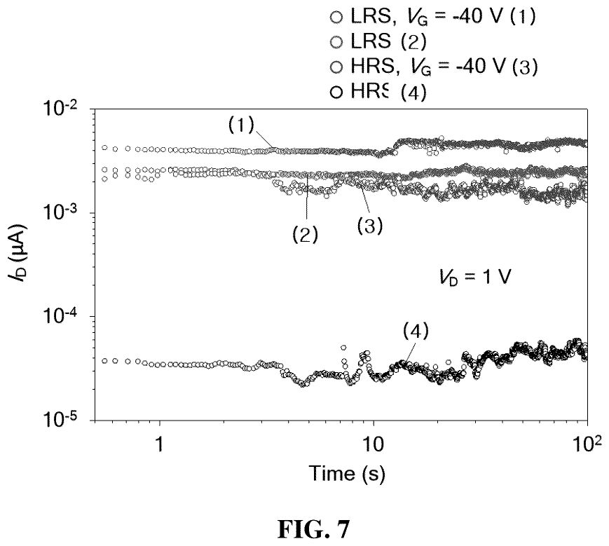

FIG. 7 is a view showing the results of measuring current retention characteristics according to various driving conditions in a time series in a memtransistor device according to the disclosure.

The experiment was performed for approximately 100 seconds at a constant read voltage of 1 V on the HₓK₁₋ₓGaSb₂ memtransistor, and was designed to evaluate the retention characteristics of the device state as well as the synaptic behavior. Measurements were made for a total of four states, which are as follows:

$$LRS , gate voltage = 0 V . \qquad 1$$

$$LRS , gate voltage = - 40 V . \qquad 2$$

$$HRS , gate voltage = 0 V . \qquad 3$$

$$HRS , gate voltage = - 40 V . \qquad 4$$

Here, LRS and HRS are respectively defined by the spatial distribution of K⁺ ions inside the device. This corresponds to the first driving principle. The gate voltage controls the conductance of the channel according to the second driving principle. Since this device has p-type semiconductor characteristics, when a negative gate voltage is applied, the hole concentration increases, thereby increasing the channel conductivity.

As a result of the measurement, the lowest current value was maintained among all conditions in the HRS state, and a relatively high current was maintained in the LRS state. In addition, a high current value was maintained at the gate voltage of −40 V. In addition, it can be confirmed that the current is stably maintained for about 100 seconds under all conditions, and the nonvolatile memory characteristics of the memtransistor are strongly revealed.

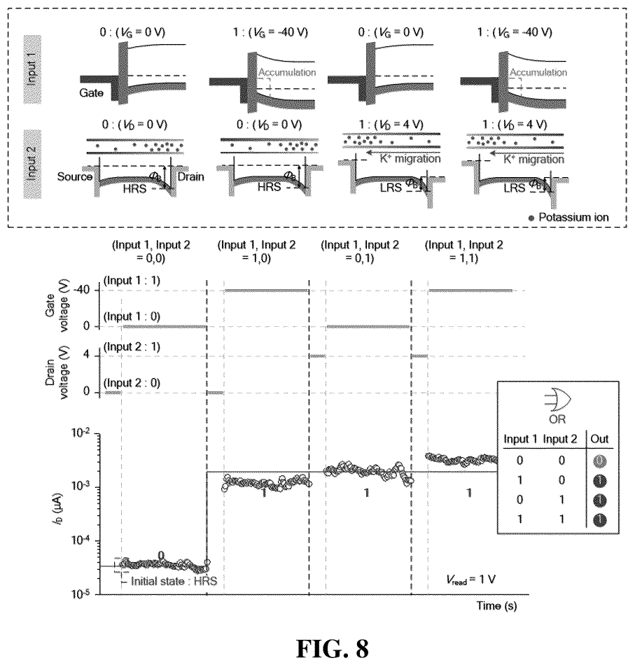

FIG. 8 is a view showing the result of implementing an OR gate using the memtransistor device of the disclosure. To implement the OR logic operation, two inputs were defined.

$$0 : gate voltage = 0 V , 1 : gate voltage = - 40 V \qquad Input 1 ( gate input )$$

$$0 : drain voltage = 0 V , 1 : drain voltage = + 4 V \qquad Input 2 ( drain input )$$

The gate voltage was applied in real time during the measurement (read stage), and the drain voltage was applied only during the programming stage to induce ion movement. The output during the read stage was always measured at a drain voltage of 1 V.

The experiment was divided into four stages, and the input combinations were applied in the order of the OR truth table, (0,0), (1,0), (0,1), (1,1). The initial state was set to HRS.
(0,0): No voltage was applied, and HRS was maintained because neither the ion distribution nor the channel doping changed. The output current was low, and the logic value was interpreted as 0.
(1,0): Gate voltage=−40 V was applied. Only the conductivity was increased. There was no ion movement, but the output current increased due to the semiconductor doping effect, and the logic value was interpreted as 1.
(0,1): Drain voltage=4 V was applied. As K⁺ ions move toward the Source, they are transferred to the LRS. During the read phase, high current was maintained and the logic value was interpreted as 1.
(1,1): The condition where both inputs are 1, the LRS state and gate doping acted simultaneously to show the highest current. The logic value was interpreted as 1.

In this result, the output sequence is (0,1,1,1), which is consistent with the truth table of the OR gate, proving that the memtransistor device of the disclosure can effectively perform logic operations using gate doping and ion movement. In particular, it was experimentally verified that OR logic operation implementation is possible when the initial state is HRS.

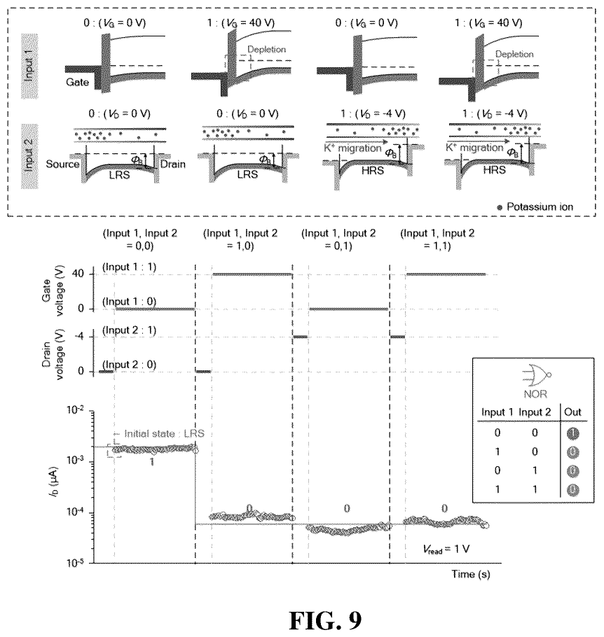

FIG. 9 is a view showing the result of implementing a NOR gate using the memtransistor device of the disclosure.

Based on the same structure and principle as the OR gate above, complementary logic operations were implemented by reversing the polarity of the initial state and input voltage.

$$0 : gate voltage = 0 V , 1 : gate voltage = + 40 V \qquad Input 1 ( gate input )$$

$$0 : drain voltage = 0 V , 1 : drain voltage = - 4 V \qquad Input 2 ( drain input )$$

The initial state was set to LRS. That is, K⁺ ions are already distributed on the source side, and it starts from a state of high conductivity. When a negative voltage is applied to the drain, the ions move back toward the drain and transition to the HRS state. In addition, when a positive voltage is applied to the gate, the conductivity of the p-type channel decreases, reducing the output current.
(0,0): Since there is no voltage applied, the LRS state is maintained, and the output current is high. The logic value was interpreted as 1.
(1,0): Gate voltage=+40 V was applied. The channel conductivity decreases, resulting in lower output current and a logic value of 0.
(0,1): Drain voltage=−4 V was applied. As ions move toward the drain, they are converted to HRS, and the output current decreases. The logic value was interpreted as 0.
(1,1): When both inputs are 1, the conduction reduction and HRS transition effects occur simultaneously, resulting in the lowest output current. The logic value was interpreted as 0.

The final output is (1,0,0,0), which exactly matches the NOR truth table. This experiment shows that the opposite logic operation can be implemented in the same device by only adjusting the initial state and the polarity of the input voltage. This strongly proves that the memtransistor of the disclosure is a device that can perform logic functions despite its simple structure.

These experimental results show that the HₓK₁₋ₓGaSb₂ memtransistor can directly perform logic operations without a separate complex circuit configuration by simultaneously utilizing the resistance change based on ion movement and the semiconductor gate voltage response characteristics within a simple device structure. In particular, the disclosure is evaluated to have secured both efficiency and versatility of memtransistor-based logic gate implementation in that complementary logic operations such as OR and NOR can be implemented by only changing the initial state of the device. In addition, this implementation principle can be directly applied to the above-mentioned group III-V two-dimensional semiconductor material having the chemical formula M₁₋ₓA_{y}B_{z}.

### <Analysis of Synaptic Weight Change and STDP Characteristics According to Gate Voltage>

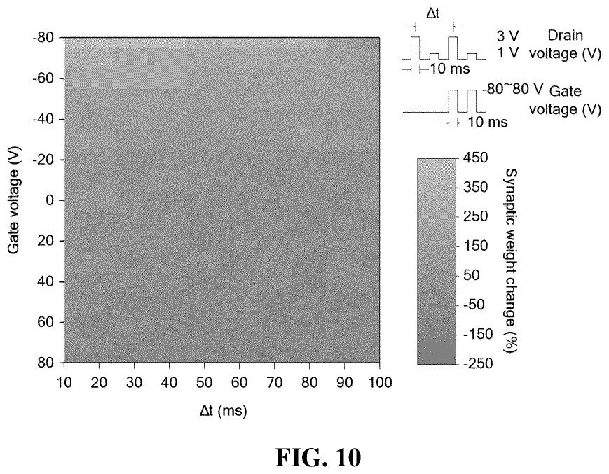

FIG. 10 is a view showing the change in synaptic weight change according to gate voltage.

In fact, when the gate voltage is negative, the value of G_{After} increases and the synaptic weight change increases significantly, while when the gate voltage is positive, the value of G_{After} decreases and the synaptic weight change tends to decrease to a negative value.

When checking the change in synaptic weight change value (STDP) according to the pulse interval at each gate voltage, it was confirmed that the closer the pulse interval, the larger the synaptic weight change value. This shows that STDP is observed consistently regardless of the gate voltage.

### <Implementation of Gate-Tunable STDP Through Dual Control of Time Interval and Gate Voltage>

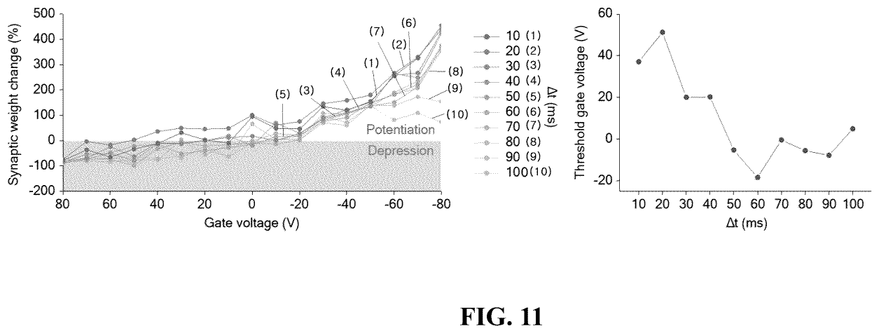

FIG. 11 is a view showing the change in synaptic weight change when gate voltage is applied according to time interval.

When checking the synaptic weight change value when the gate voltage is applied according to each time interval, it can be confirmed that the closer the time interval, the higher the synaptic weight change value. In addition, there was a specific gate voltage (called threshold gate voltage) at which the synaptic weight change according to each time interval changed from Potentiation to Depression depending on the value of the gate voltage. The shorter the pulse interval, the more positive gate voltage was required to change from Potentiation to Depression. Considering that it is a p-type semiconductor, it can be seen that a positive gate voltage is needed to further reduce the conductance.

Therefore, a method of driving a memtransistor synaptic device according to an embodiment of the disclosure can be characterized by applying a first pulse to the drain electrode to induce the movement of M⁺ ions in the semiconductor layer to change the electric conductivity (resistance state) of the semiconductor layer, and at the same time applying a gate voltage corresponding to a second pulse that can precisely control this to the substrate (2 Driving Principle).

In conclusion, the disclosure may provide a synaptic device that can control LTP/LTD and implement gate-tunable STDP by simultaneously utilizing ion movement and semiconductor properties within the van der Waals gap for the first time. In the case of van der Waals gap materials (TMDC, Graphene, etc.) corresponding to existing semiconductor layers, since ions change to metallic properties within the van der Waals gap, it may be difficult to apply the driving method of such a synapse-mimetic device, so the configuration of the disclosure is differentiated from existing devices.

The description of the disclosure is for illustrative purposes, and those skilled in the art will understand that it can be easily modified into other specific forms without changing the technical idea or essential features of the disclosure. Therefore, the embodiments described above should be understood as being exemplary in all respects and not limiting. For example, each component described as a single type may be implemented in a distributed manner, and likewise, components described as distributed may be implemented in a combined form.

The scope of the disclosure is indicated by the following claims, and all changes or modifications derived from the meaning and scope of the claims and their equivalent concepts should be interpreted as being included in the scope of the disclosure.

What is claimed is:

1. A memtransistor device comprising:
a substrate;
a dielectric layer disposed on the substrate;
a group III-V two-dimensional semiconductor layer disposed on the dielectric layer; and
source and drain electrodes disposed on the group III-V two-dimensional semiconductor layer and spaced apart from each other.

2. The memtransistor device of claim 1, wherein the group III-V two-dimensional semiconductor layer is a layered compound represented by chemical formula 1: 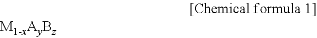
wherein the M is at least one of a group 1 element or a group 2 element, the A is a group III metal element, the B is a group V element, and the x, y and z satisfy 0<x≤1.0, 0<y≤2.25, and 0<z≤2.25.

3. The memtransistor device of claim 2, wherein the layered compound further comprises H and is represented by chemical formula 2:

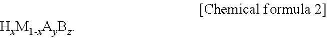

4. The memtransistor device of claim 2, wherein the layered compound comprises at least one of M₁₋ₓGa_{y}Sb_{z}, M₁₋ₓAl_{y}Sb_{z}, M₁₋ₓGa_{y}N_{z}, M₁₋ₓGa_{y}As_{z}, M₁₋ₓIn_{y}As_{z}, M₁₋ₓIn_{y}P_{z}, M₁₋ₓGa_{y}P_{z} or M₁₋ₓIn_{y}Sb_{z}.

5. The memtransistor device of claim 1, wherein the source and drain electrodes define a Schottky junction with the group III-V two-dimensional semiconductor layer.

6. A memtransistor synapse device, comprising:
a substrate;
a dielectric layer disposed on the substrate;
a group III-V two-dimensional semiconductor layer disposed on the dielectric layer; and
source and drain electrodes disposed on the group III-V two-dimensional semiconductor layer and spaced apart from each other.

7. The memtransistor synapse device of claim 6, wherein the group III-V two-dimensional semiconductor layer is represented by chemical formula 1: 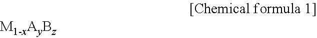
wherein the M is at least one of a group 1 element or group 2 element, the M exists in a cationic state between two-dimensional material layers, the A is a group III metal element, the B is a group V element, and x, y and z satisfy 0<x≤1.0, 0<y≤2.25, and 0<z≤2.25.

8. The memtransistor synapse device of claim 7, wherein by applying a first pulse to the drain electrode, a movement of M⁺ ions in the group III-V two-dimensional semiconductor layer is induced to change an electrical conductivity of the group III-V two-dimensional semiconductor layer.

9. The memtransistor synapse device of claim 8, wherein by applying a second pulse to the substrate, the electrical conductivity of the group III-V two-dimensional semiconductor layer is changed.

10. The memtransistor synapse device of claim 8, wherein the first pulse is a positive voltage, and by repeatedly applying the first pulse, the electrical conductivity of the group III-V two-dimensional semiconductor layer is increased to implement long-term potentiaton (LTP).

11. The memtransistor synapse device of claim 8, wherein the first pulse is a negative voltage, and the first pulse is repeatedly applied to reduce the electrical conductivity of the group III-V two-dimensional semiconductor layer to implement long-term depression (LTD).

12. The memtransistor synapse device of claim 9, wherein the first pulse comprises 1A pulse and 1B pulse applied at intervals, and the second pulse is applied while the 1B pulse is applied.

13. A memtransistor logic gate device, comprising:
a substrate;
a dielectric layer disposed on the substrate;
a group III-V two-dimensional semiconductor layer disposed on the dielectric layer; and
source and drain electrodes disposed on the group III-V two-dimensional semiconductor layer and spaced apart from each other.
